(19) United States
(12) Patent Application Publication
(10) Pub. No.: US 2010/0201228 A1
(43) Pub. Date: Aug. 12, 2010

(54) METHOD OF COATING

(75) Inventors: Saden Heshmatllah Zahiri, Victoria (AU); Mahnaz Zehtab Jahedi, Victoria (AU); Peter Christopher King, Victoria (AU); James Friend, Victoria (AU)

Correspondence Address: NIXON & VANDERHYE, PC, 901 NORTH GLEBE ROAD, 11TH FLOOR, ARLINGTON, VA, 22203, US

(73) Assignees: COMMONWEALTH SCIENTIFIC AND INDUSTRIAL RESEARCH ORGANISATION, Campbell, Australian Capital Territory (AU); MONASH UNIVERSITY, Clayton (AU)

(21) Appl. No.: 12/448,350

(22) PCT Filed: Dec. 18, 2007
(86) PCT No.: PCT/AU2007/001948

§ 371 Date: Mar. 15, 2010

(30) Foreign Application Priority Data
Dec. 18, 2006 (AU) 2006907043
Jul. 4, 2007 (AU) 2007903632

(51) Int. Cl. H01L 41/22; H01L 41/047

(52) U.S. Cl. 310/365; 29/25.35; 427/100

(57) ABSTRACT

The present invention provides a method of depositing a metallic layer on to a surface of a piezoelectric substrate, which method comprises the application of cold spraying to deposit the metallic layer or layers.

The present invention relates to a method of depositing a metallic coating onto the surface of a piezoelectric material. The present invention also relates to a coated piezoelectric material when produced in accordance with the present invention. The present invention may be especially useful for the manufacture of piezoelectric transducers.

### BACKGROUND OF THE INVENTION

Piezoelectric materials transform energy between mechanical and electrical forms. Thus, the application of a physical stress to a piezoelectric material generates an electric charge, and the application of an electric charge a piezoelectric material results in physical stress (motion) within the material. A variety of ceramic materials have this piezoelectric characteristic, and these include but are not limited to materials such as barium titanate (BaTiO₃), lead titanate (PbTiO₃), solid solutions of PbZrO₃ and PbTiO₃ (lead zirconate titanate Pb(Zr,Ti)O₃, known as PZT), and many types of lead-free materials, including zinc oxide (ZnO), aluminium nitride (MN), and single crystal materials like lithium niobate (LiNbO₃), lithium tantalate (LiTaO₃), quartz, langasite (La₃Ga₅SiO₁₄) and gallium orthophosphate (GaPO₄). Doping elements such as niobium, lanthanum and others, may also be used to alter or enhance material properties to meet specific requirements.

Metallic electrodes, on opposing faces of a piezoelectric ceramic material, allow the application of a uniform electric field across the material. This is necessary for poling, a procedure employed during manufacture of a piezoelectric device, in which a voltage is applied at an elevated temperature, resulting in a net polarisation that remains in the piezoelectric material. Electrodes are also needed for input/output of electrical signals during service.

A well known form of device utilising piezoelectric materials is the “Langevin” transducer used in marine sonar applications. These transducers typically include a piezoelectric element clamped between two masses. A problem that arises with this arrangement is that piezoelectric material cracking and depolarization can arise from excessive clamping forces. In medium to small devices using piezoelectric materials, metallic electrodes are typically bonded to the surface of a piezoelectric material.

It has been common practice for external electrodes to be adhesively bonded to the surfaces of a piezoelectric material and number of different methods are currently used. One method involves the use of an epoxy adhesive or dental cement (Al₂O₃) to bond the electrodes to the surfaces of a piezoelectric substrate. This approach is typically employed in small devices such as ultrasonic motors used for ultrasonic cleaning. These motors include piezoelectric elements that are bonded together using an epoxy bond. Epoxy bonding is also used in “Baltan” microactuators having a fumed element bonded to a stepped piezoelectric substrate. Epoxy bonding does however have substantial disadvantages. Thus, it has been found that a significant percentage of the mechanical vibration energy transmitted from a piezoelectric substrate is lost in the epoxy bond in many commercial devices. Furthermore, the mechanical strength and delamination of the epoxy-bonded piezoelectric elements within ultrasonic motors is a common problem. Furthermore, electrical conductivity of epoxy bonds is relatively poor. The conventional techniques described for bonding external electrodes on piezoelectric materials may suffer from surface roughness effects that result in localized stress and temperature concentrations that affect performance.

In more recent microactuator and microsensor applications, alternative methods have been sought to bond the metallic electrodes to the piezoelectric substrates. These methods include vacuum sputtering or vapour deposition of the electrodes onto that substrate surface. A further alternative is to apply a silver-loaded paint to the surface of the piezoelectric material. The paint then needs to be cured using an external source of heat. These methods are however time consuming, and the bond strength of the metallic film is typically less than the strength of the piezoelectric substrate itself. Furthermore, the maximum thickness of a sputtered or vapour deposited film is limited. Therefore, this limits the amount of heat that can be applied to the film, making it difficult to use micro soldering processes to attach chips to such piezoelectric transducers. Moreover, excessive heating of the metallic film and the underlying piezoelectric substrate could result in the temperature of the substrate exceeding the Curie temperature leading to depolarization of the piezoelectric material.

Any discussion of documents, systems, acts or knowledge in this specification is included to explain the context of the invention. It should not be taken as an admission that any of the material formed part of the prior art base or the common general knowledge in the relevant art in or any other country on the priority date of the claims therein.

### SUMMARY OF THE INVENTION

The present invention seeks to overcome at least some of the disadvantages associated with known metallic bonding methods as described above.

Accordingly, the present invention provides a method of depositing a metallic layer on a surface of a piezoelectric substrate, which method comprises cold spraying metallic particles onto the substrate to provide the metallic layer. The present invention also provides a piezoelectric substrate produced in accordance with the method of the present invention.

In another embodiment the present invention provides the use of cold spraying to provide a metallic film on the surface of a piezoelectric substrate.

The method of the present invention involves cold spraying (otherwise known as cold-gas dynamic spraying or dynamic metallisation) of metallic particles at high velocity onto a piezoelectric substrate in order to provide a metallic film coating having suitable surface characteristics for use as electrodes. Cold spraying is a known process for applying coatings to surfaces.

Cold spray systems include a converging-diverging (Laval) type nozzle, through which a heated, high pressure gas is compressed and then expanded to atmospheric pressure thereby resulting in acceleration of the gas stream to very high velocities and cooling of the gas stream. Metallic powder is fed into and becomes entrained in the gas stream, the metallic powder being subsequently sprayed onto the surface of a substrate to be coated. The velocity of the gas stream may be in the order of between 300 to 2000 m/s, whereas the size of the metal particles forming the metallic powder may be from 1 to 100 for example from 1 to 50 μm. The process is carried out at relatively low temperatures, below the melting point of the particles and the substrate to be coated, with a coating being formed as a result of particle impingement on the substrate surface. The fact the process is carried out at relatively low temperature prevents high temperature oxidation, evaporation, melting, recrystallisation and gas evolution of the powder thereby providing many inherent advantages over existing coating methods. This means that the original structure and properties of the particles can be preserved without phase transformations, etc. that might otherwise be associated with high temperature coating processes such as plasma, HVOF, arc, gas-flame spraying or other thermal spraying processes. The underlying principles, apparatus and methodology of cold spraying are described, for example, in U.S. Pat. No. 5,302,414.

While the use of cold spray deposition of metallic particles onto a variety of substrates has been achieved, it has not been previously considered possible to do so on piezoelectric substrates. The applicant has however successfully deposited metals onto such ceramic materials.

In accordance with the present invention it has been found possible to produce a suitably adherent and low porosity metallic coating on a piezoelectric substrate based on the characteristics of the metallic particles to be sprayed and the cold spray operating parameters.

### DETAILED DISCUSSION OF INVENTION

In accordance with the present invention metallic electrode coatings are provided on the surfaces of a piezoelectric substrate by cold spraying of metal particles onto the piezoelectric substrate. The particles may be of any suitable metal or mixture of metals. The metallic coating should be sufficiently ductile and not too hard to cause damage to the piezoelectric material upon which the particles are being sprayed, although the prevailing temperature and/or particle velocity may be manipulated to minimise any adverse effect that particle impact has on the surface of the piezolelectric material. Aluminium is a preferred metal to use since aluminium particles deform easily upon impact at the substrate surface. Aluminium also has low density so that individual particles masses tend to be low. One skilled in the art will be familiar with other metals or metal alloys that may be useful in practice of the present invention.

Depending upon the nature of the metal used to provide the electrode coating on the piezoelectric substrate, it may be necessary to apply a further top coat over the electrode coating. For example, and as noted, it has been found that aluminium particles can be used to form an electrode coating on piezoelectric ceramics. However, aluminium is not easily wetted by electrical solder (used for making/securing electrical contacts with the electrodes) and a top coat of another metal or metal alloy having enhanced wettability with respect to the solder may be applied. The top coat is also produced by cold spraying of metallic particles. Typically, the top coat will be formed of copper or a tin-based solder alloy.

The average particle size of the metal particles is likely to influence the density of the resultant coating. Preferably, the coating is dense and free from defects, micro-voids, and the like, since the presence of such can be detrimental to the quality and properties of the resultant electrodes. Typically, the average particle size is typically less than 50 μm and preferably less than 25 μm. The average particle size should also be selected to minimise damage to the underlying piezoelectric substrate material. One skilled in the art will be able to determine the optimum particle size or particle size distribution to use based on the morphology and characteristics of the layer that is formed by cold spraying and on the effect that cold spraying has on the piezoelectric substrate. Metal particles suitable for use in the present invention are commercially available.

Usually, the thickness of the electrode layer will be from 50-250 μm. The electrode layer is made up by a succession of particle impacts on the surface of the piezoelectric substrate so it will be appreciated that when the layer thickness is at the lower end of this range, the average particle size will be somewhat less than 50 μm. When used the top coat layer will have a typical thickness of from 50-250 μm, noting the comments above in relation to average particle size of constituent particles making up the layer. Metallic particles useful in this invention are commercially available.

The piezoelectric substrate material is of conventional type and may be formed of the materials noted above. The invention has been found to work well using PZT as the piezoelectric material. In that case it has also been found useful to employ aluminium as the electrode layer and cooper as the top coat layer.

The operating parameters for the cold spray process may be manipulated in order to achieve a coating that has desirable characteristics (density, surface finish etc). Thus, parameters such as temperature, pressure, stand off (distance between nozzle and substrate surface), powder feed rate and the like may be adjusted. One skilled in the art would be able to manipulate the various parameters in order to achieve optimum results. The apparatus used for the cold spray process is likely to be of conventional form, and such equipment is commercially available. In general terms the basis of the apparatus used for cold spraying will be as described and illustrated in U.S. Pat. No. 5,302,414.

In an embodiment of the invention the cold spray methodology is applied to provide a multi-layered structure. For example, the methodology may be applied to produce a first coating that is an intermediate layer intended to produce a layer that facilitates bonding of a subsequently applied second layer. The second layer may be provided to provide enhanced soldering properties and this results in improved electrical contact between the piezoelectric substrate and electrical contacts. The first layer may suitably be aluminium.

The use of cold spray technology to apply metal electrode coatings to piezoelectric substrates has a number of advantages, some of which are listed below
a) The metal being applied does not need to be chemically compatible with the piezoelectric substrate as is the case with chemical vapour deposition methods.
b) The thickness of the metal coating being applied to the substrate can be much higher than could be the case with vacuum sputtering or chemical vapour deposition methods. This facilitates the use of micro soldering manufacturing methods, for example for attaching chips to transducers.
c) As the method takes place at low temperatures, there is minimal possibility of the Curie temperature of the piezoelectric substrate being exceeded.
d) The speed and flexibility of the cold spray process is a clear advantage over thin film techniques and other electroding technologies that require lengthy batch processing. In contrast, cold spray is readily compatible with assembly-line manufacture.
e) A broader range of material sizes and shapes can be coated than by vacuum deposition techniques.

### BRIEF DESCRIPTION OF THE DRAWINGS

It will be convenient to further describe the invention with respect to the accompanying non-limiting drawings which illustrate embodiments of the present invention

FIG. 1 is a schematic view of the process of particle acceleration and deposition onto a piezoelectric substrate.

FIG. 2 is an optical micrograph of a cross section of a PZT substrate, coated with two metallic layers by cold spray, the first aluminium, the second copper.

FIG. 3 is a secondary electron image of PZT microstructure.

FIG. 4 is an optical micrograph of a coating cross-section, unetched. The arrow shows cracking in PZT surface that causes delamination of the coating.

FIG. 5 is a secondary electron image of an etched aluminium coating microstructure.

FIG. 6 illustrates cold spray coated PZT devices.

FIG. 7 is an optical micrograph showing in cross-section a duplex coating on a published PZT substrate.

FIG. 8 is an optical micrograph showing in cross-section the PZT-Al interface after cold-spraying.

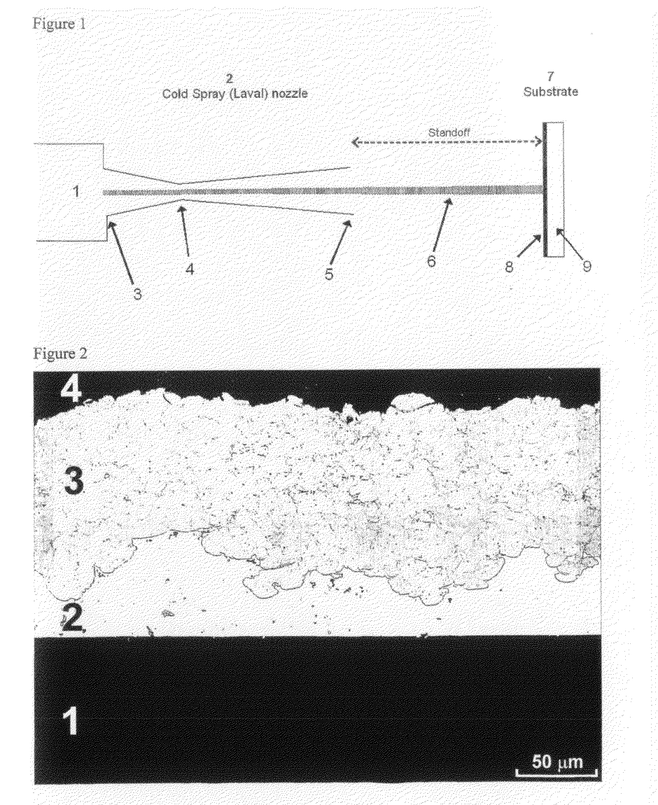

Referring to FIG. 1, the method according to the present invention utilises a cold spray system for spraying metallic powder onto the surface of a piezoelectric substrate. Heated, high pressure gas 1 is fed through a converging-diverging (Laval) type nozzle 2. There are a number of different gas compositions which may be used, that include but are not limited to; air, nitrogen, helium, Argon or a mixture of two or more of these. The configuration of the Laval nozzle 2 with a converging inlet 3 and a diverging outlet 5 means that gas supplied to the nozzle inlet 3 is accelerated as it passes through the throat portion 4 of the nozzle between the inlet and outlets 3, 5 thereof. Metallic powder is fed into the gas stream at some point, for example in the high pressure region 1 upstream from the nozzle, or at the exit 5, so that it becomes entrained in the flow and is accelerated to high velocities. As the heated gas passes through the nozzle 2, the gas is initially compressed and expanded to thereby cool the gas stream. The temperature of the gas within the high velocity spray 6 therefore remains significantly lower than the melting temperature of the powder material.

The nozzle 2 is kept at a certain standoff distance from the substrate 7, typically 5-100 mm. Impact of the metallic powder in the jet stream 6 onto the substrate 9 causes the powder particles to plastically deform and bond onto said surface. In some cases it may not be necessary to heat the gas stream 1 prior to entry to the nozzle 2, if the powder particles being sprayed still attain sufficient velocity to plastically deform extensively upon impact with the substrate 7. The nozzle 2 can be attached to a robot arm to allow for precise control of the position of the nozzle 2, and is typically scanned laterally across the substrate surface 7 in a raster pattern. This allows for a progressive increase in the thickness of the coating 8 of the metal on the piezoelectric substrate 9.

Embodiments of the present invention are illustrated in the following non-limiting examples.

### EXAMPLE 1

One example of a metallic coating deposited on the surface of a piezoelectric substrate by the inventor using the method described is shown in FIG. 2. Shown in this figure is an optical micrograph of a cross-section of the substrate 1 and the coating layers 2 and 3. The cross-section was mounted in resin 4 and polished for metallographic inspection. The first coating layer 2 was aluminium and the second coating 3 layer was copper. The aluminium layer was deposited using a nitrogen gas stream heated to 150° C. at a pressure of 24 MPa, while the copper layer was deposited using a nitrogen gas stream heated to 400° C. at a pressure of 24 MPa. The standoff distance of the nozzle from the substrate was 20 mm. In the example shown here, the substrate 1 was polycrystalline lead zirconate titanate (PZT). This particular substrate material was prone to erosion by the particle-laden jet and depolarisation of the surface layers unless the following preventative measures were taken:
1. The coating particles should be sufficiently ductile, and not too massive to cause damage to the substrate. For this reason, aluminium was chosen, because aluminium particles deform easily upon impact against the substrate. Aluminium also has a low density, so the individual particle masses were low.
2. The size of the particles should be limited (typically to a diameter of less than 50 microns, or preferably less than 25 microns) which ensures that the particle mass will not be too large to cause excessive damage to the substrate.

Without these precautions, damage to the substrate surface may result in a poor bond forming between the coating and the piezoelectric substrate, delamination of the coating, failure of the piezoelectric component during service, or complete inability to apply a cold spray coating onto the piezoelectric material at all. Other piezoelectric materials may not be so easily damaged by the cold spray process, and so these preventative measures may not be necessary. In particular, the inventor has found that the level of porosity of the substrate is an important consideration—ceramic materials with a density closer to the theoretical density are less susceptible to erosion. Depolarisation of the surface layers may occur to a lesser or greater extent, depending on the ferroelectric properties of the substrate.

Following deposition of the aluminium bonding layer, copper was deposited to form an outer top coat. This was done because the copper top coat is more easily wetted by solder than aluminium. However, the choice of coating materials is not limited to aluminium and copper—other topcoat materials may be cold sprayed, including tin or solder alloys (tin-based alloys).

### EXAMPLE 2

Commercial PZT elements were used for the following experiments. 20 mm diam., 1 mm thick discs and 1×1×5 mm rods (C-203, Fuji Ceramics, Tokyo, Japan) were supplied with sputtered electrodes and polarized. The direction of polarization was in the thickness direction for the discs, and lengthwise for the rods.

Prior to cold spray, the original electrodes were removed by manual grinding with SiC paper. In some cases the surface was further polished down to a final stage with 1 μm diamond solution on a felt pad. Aluminium coatings were then deposited using a CGT™ Kinetic 3000 cold spray system. The aluminium feedstock powder was 99.7% Al, with median particle size 21.3 μm. Nitrogen was used as the carrier gas. Stagnation conditions at the entry point to the nozzle were 100-350° C., 2.4 MPa. The nozzle was attached to a robot arm, aimed perpendicularly to the PZT substrate at a standoff distance of 20 mm, and was moved laterally in an X-Y raster pattern at 300 cm/min to cover the entire face of the sample. Following aluminium coating, a layer of copper was deposited using oxygen free, high conductivity (OFHC) copper powder, with stagnation conditions 200-400° C., 2.6 MPa.

Optical micrographs (OM) of coating-substrate cross sections were taken by mounting in bakelite and polishing using standard metallographic techniques. Scanning electron microscopy (SEM) was performed on a Leica 440 SEM, with a tungsten filament source and an accelerating voltage of 20 kV.

The PZT material used in the experiments was a fine-grained ceramic containing a significant amount (˜5%) of porosity. Etching with 0.5% HF/1% HNO₃ solution revealed the grain boundaries and ferroelectric domains (FIG. 3).

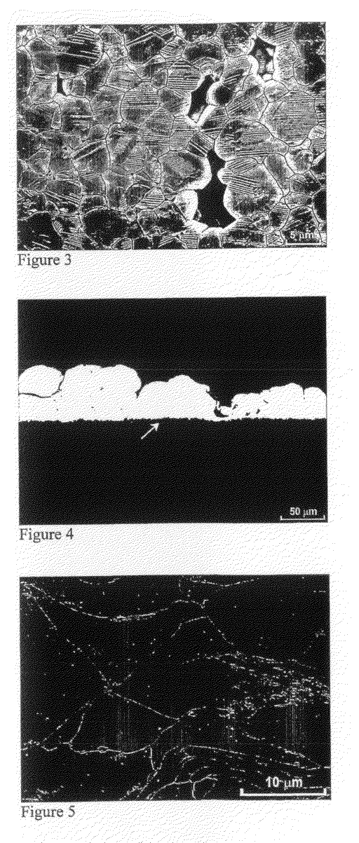

Under non-optimum coating conditions, where aluminium particles were not sufficiently accelerated prior to impact, shock-induced damage to the PZT surface occurred, with fracture along grain boundaries (FIG. 4). The arrow shows an area that has begun delaminating, where failure has occurred within the substrate, one or two grain diameters below the aluminium-PZT interface. The coating morphology shows that limited deformation and flattening of the aluminium particles has occurred, leading to higher coating porosity.

By raising the jet temperature, higher particle velocities are achieved and thermal softening of the aluminium improves its deformability. FIG. 5 shows an aluminium coating formed with the carrier gas preheated to 200° C. The inter-particle boundaries were revealed by etching with 0.5% HF/1% HNO₃ solution. Flattened, angular particle morphologies are apparent. Extensive plastic deformation has taken place, and porosity has been reduced to levels well below that of the substrate.

It is known that bonding in cold spray is highly dependent on the process of particle deformation. Hard, brittle materials cannot be cold sprayed due to their limited ability to plastically deform. During the impact of ductile metallic particles, intense shearing at particle/particle (or particle/substrate) interfaces leads to the formation of material jets, which break down surface oxide films, allowing intimate metal-on-metal contact and the formation of strong, metallurgical bonds. While this mechanism can be applied to explain the strong interparticle bonding within the aluminium coating, it is not yet clear, without further fundamental study, how metallic particles are able to bond to ceramic surfaces.

Nevertheless, with higher jet temperatures, there is greater energy loss through permanent deformation and the elastic rebound energy is diminished. The result is that deposition efficiency greatly increases with higher jet temperatures. Damage to the substrate is reduced in two ways. Firstly, the coating builds up more quickly, meaning fewer non-bonding impacts. Secondly, higher jet temperatures soften the impacting particles. Increasing the jet temperature further, however, results in coating failure due to the difference in thermal expansion coefficient between aluminium and the ceramic.

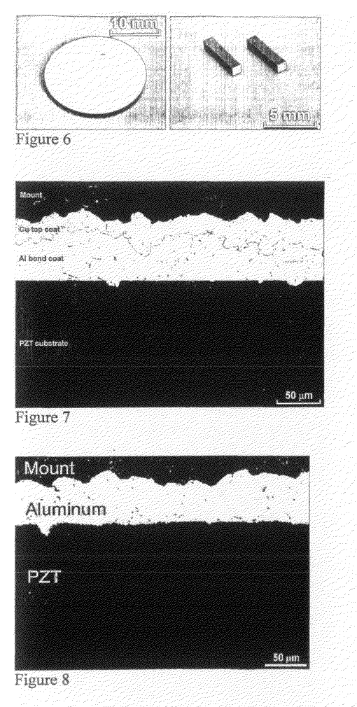

Under optimum conditions, dense, well adhered aluminium bondcoats can be deposited on PZT substrates of various sizes (FIG. 6). If the aluminium layer is well bonded, a copper topcoat can then be deposited to create a solderable surface (FIG. 7). Copper has a higher density than aluminium (8.9 g/cm³ versus 2.7 g/cm³), so the copper particles penetrate deeply into the bondcoat, and the copper-aluminium interface is interlocked. Failure therefore typically only occurs near the aluminium-PZT boundary. Polishing of the substrate prior to spray further minimizes damage to the PZT and the possibility of intergranular fracture seen earlier. A certain degree of mechanical adhesion takes place even on smooth substrates by penetration of the aluminium into open pores at the surface (FIG. 7).

### EXAMPLE 3

Hard PZT elements (C213 material, Fuji Ceramics, Tokyo Japan), 020×10 mm thick, thickness polarised and sputter electroded on both planar faces with nickel were obtained for this project. The impedance characteristics of the original elements were measured (4294A, Agilent, Palo Alto, Calif. USA) for later comparison about the fundamental resonance (about 99 kHz) and antiresonance (about 120 kHz) using a sinusoidal input signal at 500 Mv_{RMS}. On the planar surfaces of the PZT elements that were to be cold sprayed, the original puttered electrodes were removed by manual grinding with 240-grit silicon carbide paper.

Aluminium coatings (FIG. 8) were then deposited using a CGT™ Kinetic 3000 cold spray system. The deposition process took about 30 seconds. Notice the low porosity in the Al coating. The piezoelectric material has some porosity, perhaps part of the reason the composition has a density of 7800 kg/m³, slightly less than theoretical, 8000 kg/m³.

The cold-spray process did not noticeably affect the polarisation of the piezoelectric material, indicating the ability to electrode the ceramic without requiring repolarisation. The low jet temperatures ensured that the substrate was not heated to near the Curie point (315° C.), which would have caused domain disorientation and depolarisation of the material. The coupling coefficient for thickness-mode vibration, k_{T}, was identical to those samples with the original electrodes left intact (cold sprayed samples k_{T}=0.552, standard dev. 1.24×10⁻³, versus sputtered samples k_{T}=0.551, standard dev. 1.62×10⁻⁴).

By using this approach to deposit thin metal films onto piezoelectric substrates, electrodes appropriate for high-power ultrasonics and inexpensive sensors and actuators may be easily formed. The cold-spray technique is compatible with masking and lift-off technologies, and therefore patterning of the electrodes is possible.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference to any prior art in this specification is not, and should not be taken as, an acknowledgment or any form of suggestion that that prior art forms part of the common general knowledge in Australia or in any other country.

1. A method of depositing a metallic layer on a surface of a piezoelectric substrate, which method comprises cold spraying metallic particles onto the substrate to deposit the metallic layer.

2. The use of cold spraying to provide a metallic layer onto a piezoelectric substrate.

3. A piezoelectric device produced by the method of claim 1.

4. A piezoelectric device produced by the use of claim 2.
